(19) United States
(12) Patent Application Publication
(10) Pub. No.: US 2015/0064559 A1
(43) Pub. Date: Mar. 5, 2015

(54) ELECTRODE-ACTIVE MATERIAL, LITHIUM-ION BATTERY, METHOD FOR DETECTING DISCHARGE STATE OF ELECTRODE-ACTIVE MATERIAL, AND METHOD FOR MANUFACTURING ELECTRODE-ACTIVE MATERIAL

(71) Applicant: SUMITOMO OSAKA CEMENT CO., LTD., Tokyo (JP)

(72) Inventors: Kouji Oono, Tokyo (JP); Satoru Oshitari, Tokyo (JP); Kazuyo Yamamoto, Tokyo (JP)

(21) Appl. No.: 14/388,431

(22) PCT Filed: Mar. 11, 2013
(86) PCT No.: PCT/JP2013/056593

§ 371 Date: Sep. 26, 2014

(30) Foreign Application Priority Data
Mar. 30, 2012 (JP) 2012-078859
Mar. 30, 2012 (JP) 2012-078861

(51) Int. Cl. H01M 4/36; G01R 31/36; H01M 10/0525; H01M 4/525; H01M 4/505

(52) U.S. Cl. CPC H01M 4/366; H01M 4/525; H01M 4/505; H01M 10/0525; G01R 31/3627
USPC 429/221; 429/223; 324/426; 252/182.1

(57) ABSTRACT

An electrode-active material, a lithium-ion battery, and a method for detecting a discharge state of an electrode-active material that make it possible to realize high load characteristics, high cycle characteristics, and high energy density, have a high degree of safety and stability, and make it possible to easily detect the state of a late stage of discharge are disclosed. The electrode-active material is obtained by coating the surface of a particle containing Li_{w}AₓDO₄ with a coating layer containing Li_{y}E_{z}GO₄. In a discharge curve of the electrode-active material, a second region which follows a first region showing a substantially constant discharge potential and shows a drop in a discharge potential includes a third region in which a rate of change in a discharge potential is lower than an average rate of change in a discharge potential of the second region.

### TECHNICAL FIELD

The present invention relates to an electrode-active material, a lithium-ion battery, a method for detecting a discharge state or an electrode-active material, and a method for manufacturing as electrode-active material. More specifically, the present invention relates to an electrode-active material which is a type of phosphate-based electrode-active material having an olivine structure, and is suitable for use as an electrode material of a lithium-ion battery excellent in load characteristics, cycle characteristics, and energy density, a lithium-ion battery having an electrode that uses the electrode-active material, a method tor detecting a discharge state of the electrode-active material, and a method for manufacturing the electrode-active material.

The present application claims priority based on Japanese Patent Application No. 2012-078859 and Japanese Patent Application No. 2012-078861 filed on Mar. 30, 2012, the contents of which are incorporated herein.

### BACKGROUND ART

In recent years, as a battery expected to realize further miniaturization, weight reduction, and increase in capacity, a nonaqueous electrolytic solution-based secondary battery such as a lithium-ion battery has been suggested and put to practical use.

Such a lithium-ion battery is constituted with positive and negative electrodes having properties in which lithium ions can be reversibly removed from and inserted into the electrodes, and a nonaqueous electrolyte.

Compared to conventional secondary batteries such as a lead battery, a nickel-cadmium battery, and a nickel-hydrogen battery, the lithium-ion battery has higher energy even though the weight and size thereof are small. Accordingly, it is being used as a power supply of portable electronic instruments such as cellular phones and laptop computers. However, in recent years, the lithium-ion battery has been examined as a high output power supply of electric cars, hybrid cars, electric tools, and the like. The electrode-active material of batteries used as a high output power supply is required to exhibit high-speed charge-discharge characteristics. Moreover, smoothing of a power generation load thereof and application thereof to a large battery of a stationary power supply, a backup power supply, and the like are under examination. For the electrode-active material, long-term safety, reliability, and low cost resulting from abundant resources thereof (no problem with resource amount) are regarded as important properties.

A positive electrode of the lithium-ion battery is constituted with an electrode material containing lithium-containing metal oxide having properties in which lithium ions called a positive electrode-active material can be reversibly removed from and inserted into the electrode, a conductive aid, and a binder. By coating the surface of a metal foil called a current collector with the electrode material, the positive electrode is formed.

As the positive electrode-active material of the lithium-ion battery, generally, lithium cobaltate (LiCoO₂) is used, and in addition, lithium (Li) compounds such as lithium nickelate (LiNiO₂), lithium manganate (LiMn₂O₄), and lithium iron phosphate (LiFePO₄) are used.

Among these lithium compounds, lithium cobaltate or lithium nickelate has many problems such as toxicity to the human body or the environment, resource amount, and instability of a charge state. Furthermore, regarding lithium manganate, a problem in that the compound dissolves in an electrolytic solution at a high temperature has been pointed out.

Therefore, in recent years, a phosphate-based electrode-active material having an olivine structure that is represented by lithium iron phosphate and is excellent in long-term safety and reliability has drawn attention.

The electron conductivity of the phosphate-based electrode-active material is insufficient. Accordingly, in order to perform charge or discharge of large currents, various measures such as atomization of particles and formation of a complex of the electrode-active material and a conductive material need to be taken, and much effort is being made to achieve this.

However, when the atomization of particles or the formation of the complex using a large amount of conductive material is conducted, electrode density is reduced, and this leads to a problem of a decrease in density of a battery, that is, a decrease in capacity per unit volume. As a method for solving the problem a carbon-coating method has been found in which a solution of as organic material is used as a carbon precursor as an electron-conducting material; the solution of an organic material is mixed with particles of an electrode-active material, and then the mixture is dried; and the organic material is carbonized by performing thermal treatment on the obtained dried material in a non-oxidative atmosphere such that the surface of the particles of as electrode-active material is coated with carbon.

The carbon-coating method has excellent characteristics in which the surface of particles of an electrode-active material can be coated with the minimum amount of carbon required with extremely high efficiency, and the conductivity can be improved without greatly decreasing electrode density. Therefore, many suggestions are being offered in regard to the method.

Meanwhile, in the phosphate-based electrode-active material having an olivine structure, such as lithium manganese phosphate (LiMnPO₄) or lithium cobalt phosphate (LiCoPO₄), those elements (Mn and Co) act as a negative catalyst in carbonization of an organic material, and accordingly, it is not easy to coat the material with an excellent conductive film.

Therefore, as one of the means for solving such a problem, a method of coating the surface of lithium manganese phosphate (LiMnPO₄), which is an active material having properties of a negative catalyst, with lithium iron phosphate (LiFePO₄), which is an active material exhibiting a high degree of activity of a carbonizing catalyst, has been suggested (PTL 1). This method is effective means for forming a conductive coat on the surface of an electrode-active material exhibiting the activity of a negative catalyst in carbonization, such as lithium manganese phosphate (LiMnPO₄) or lithium cobalt phosphate (LiCoPO₄).

Meanwhile, the inventors of the present application also found the same means on their own, and suggested, as more effective means, a method of mixing an element exhibiting the activity of a carbonizing catalyst with an organic material, coating the mixture with an active material having properties of a negative catalyst, and carbonizing the resultant by heating (PTL 2).

According to this method, an element exhibiting the activity of a carbonizing catalyst has been combined with an active material having properties of a negative catalyst through an organic material. Consequentially, even in the process of heating and carbonization of the organic material, diffusion of the elements can be prevented, and even a lesser amount of a catalyst can result in sufficient carbonization activity. Therefore, a decrease in the fraction of lithium manganese phosphate (LiMnPO₄), lithium cobalt phosphate (LiCoPO₄), or the like which reacts at a higher potential can be suppressed to a minimum.

### CITATION LIST

### Patent Literature

[PTL 1] International Publication No. WO 2011/032264

[PLT 2] Japanese Laid-open Patent Publication No. 2011-181375

### SUMMARY OF INVENTION

### Technical Problem

In the conventional method of coating the surface of lithium manganese phosphate (LiMnPO₄) with lithium iron phosphate (LiFePO₄), on the surface of a particle, an active material composed of an element having properties of a negative catalyst comes into direct contact with an active material composed of an element having properties of a carbonizing catalyst. Accordingly, these elements are easily diffused under heating conditions for decomposing and carbonizing an organic material. As a result, the concentration of the element showing carbonizing activity within the surface of the active material decreases, so the concentration is not always sufficient. In order to prevent the decrease in the concentration of the element showing carbonizing activity, a layer of the active material showing carbonizing activity needs to have a certain degree of thickness. As a result, the fraction of lithium manganese phosphate (LiMnPO₄), lithium cobalt phosphate (LiCoPO₄), or the like which reacts at a higher potential decreases, and this leads to a problem in that a sufficient capacity cannot be obtained.

Although a high-potential positive electrode material having an olivine structure that is represented by lithium manganese phosphate (LiMnPO₄) or lithium cobalt phosphate (LiCoPO₄) is expected to result in high energy density, it is known that a charge and discharge reaction thereof proceeds as a two-phase reaction of an oxidation phase and a reduction phase, and the reaction potential practically remains flat until the final stage or discharge. This is advantageous for obtaining a high level of energy. However, since the voltage does not significantly drop until just prior no the end of discharge, when such a material is actually used as a battery for a power supply of a device, there is a danger that the voltage may rapidly drop at the last stage of discharge, and thus the device may malfunction.

Meanwhile, among the phosphate-based electrode-active materials, as an active material which does not impair the advantages of lithium manganese phosphate (LiMnPO₄) or lithium cobalt phosphate (LiCoPO₄) having a high degree of safety and stability and can be used for capacitive detection, lithium iron phosphate (LiFePO₄) is the best. Lithium iron phosphate (LiFePO₄) may be used in a small amount for capacitive detection, but if a small amount of LiFePO₄ is added, for the aforementioned reason, it is difficult to obtain a carbonaceous conductive coat for providing conductivity. If a large amount of LiFePO₄ is added, a carbonaceous conductive coat can be obtained, but this leads to a problem in that the fraction of an active material having high voltage decreases, and discharge capacity decreases.

The present invention has been made to solve the above problems, and an object thereof is to provide an electrode-active material, a lithium-ion battery, a method for detecting a discharge state of an electrode-active material, and a method for manufacturing an electrode-active material that make it possible to realize high load characteristics, high cycle characteristics, and high energy density, has a high degree of safety and stability, and make it possible to easily detect the state of a late stage of discharge.

### Solution to Problem

As a result of conducting thorough examination aimed at achieving the above object, the present inventors found that in a discharge curve of an electrode-active material obtained by coating the surface of a particle composed of Li_{w}ZₓDO₄ (here, A represents 1 or 2 kinds selected from the group consisting of Mn and Co, D represents 1, 2, or more kinds selected from the group consisting of P, Si, and S, 0<w≦4, and 0<x≦1.5) with a coating layer containing Li_{y}E_{z}GO₄ (here, E represents either Fe or Fe and Ni, G represents 1, 2, or more kinds selected from the group consisting of P, Si, and S, 0<y≦2, and 0<z≦1.5), a second region which follows a first region showing a substantially constant discharge potential and shows a drop in a discharge potential includes a third region in which a rate of change in a discharge potential is lower than an average rate of change in a discharge potential of the second region. The inventors found that by detecting the third region, the state of a late stage of discharge can be easily detected, and in this way, they completed the present invention.

That is, an electrode-active material of the present invention is an electrode-active material obtained by coating the surface of a particle composed of Li_{w}AₓDO₄ (here, A represents 1 or 2 kinds selected from the group consisting of Mn and Co, D represents 1, 2, or more kinds selected from the group consisting of P, Si, and S, 0<w≦4, and 0<x≦1.5) with a coating layer containing Li_{y}E_{z}GO₄ (here, E represents either Fe or Fe and Ni, G represents 1, 2, or more kinds selected from the group consisting of P, Si, and S, 0<y≦2, and 0<z≦1.5). In a discharge curve of the electrode-active material, a second region which follows a first region showing a substantially constant discharge potential and shows a drop in a discharge potential includes a third region in which a rate of change in a discharge potential is lower than an average rate of change in a discharge potential of the second region.

A capacity at 60° C. of the third region is preferably from 1/20 to ⅓ of a maximum value of a discharge capacity.

In the case, a reaction potential at 60° C. of the third region is preferably from 3.0 V to 3.8 V.

A lithium-ion battery of the present invention has a positive electrode that contains the electrode-active material of the present invention.

A method for detecting a discharge state of the electrode-active material of the present invention is a method for detecting a discharge state of an electrode-active material obtained by coating the surface of a particle composed of Li_{w}AₓDO₄ (here, A represents 1 or 2 kinds selected from the group consisting of Mn and Co, D represents 1, 2, or more binds selected from the group consisting of P, Si, and S, 0<w≦4, and 0<x≦1.5) with a coating layer containing Li_{y}E_{z}GO₃ (here, E represents either Fe or Fe and Ni, G represents 1, 2, or more kinds selected from the group consisting of P, Si, and S, 0<y≦2, and 0<z≦1.5), in which in a discharge curve of the electrode-active material, within a second region which follows a first region showing a substantially constant discharge potential and shows a drop in a discharge potential, a third region in which a rate or change in a discharge potential is lower than an average rate of change in a discharge potential of the second region is detected.

Moreover, as a result of conducting thorough examination aimed at achieving the above object, the present inventors found that in a discharge curve of an electrode-active material obtained by coating the surface of a particle composed of Li_{w}AₓDO₄ (here, A represents 1 or 2 binds selected from the group consisting of Mn and Co, P represents 1, 2, or more kinds selected from the group consisting of P, Si, and S, 0<w≦4, and 0<x≦1.5) with a coating layer composed of a complex consisting of Li_{y}E_{z}GO₄ (here, E represents either Fe or Fe and Ni, G represents 1, 2, or more kinds selected from the group consisting of P, Si, and S, 0<y≦2, and 0<z≦1.5) and a carbonaceous electron-conducting material, a second region which follows a first region showing a substantially constant discharge potential and shows a drop in a discharge potential includes a third region in which a rate of change in a discharge potential is lower than an average rate of change in a discharge potential of the second region. The inventors found that by detecting the third region, the state of a late stage of discharge can be easily detected, and in this way, they completed the present invention.

That is, the electrode-active material of the present invention is an electrode-active material obtained by coating the surface of a particle composed of Li_{w}ZₓDO₄ (here, A represents 1 or 2 kinds selected from the group consisting of Mn and Co, D represents 1, 2, or more kinds selected from the group consisting of P, Si, and S, 0<w≦4, and 0<x≦1.5) with a coating layer composed of a complex consisting of Li_{y}E_{z}GO₄ (here, E represents either Fe or Fe and Ni, G represents 1, 2, or more kinds selected from the group consisting of P, Si, and S, 0<y≦2, and 0<z≦1.5) and a carbonaceous electron-conducting material. In a discharge curve of the electrode-active material, a second region which follows a first region showing a substantially constant discharge potential and shows a drop in a discharge potential includes a third region in which a rate of change in a discharge potential is lower than as average rate of change in a discharge potential of the second region.

A capacity at 60° C. of the third region is preferably from 1/20 to ⅓ of a maximum value of a discharge capacity.

In this case, a reaction potential at 60° C. of the third region is preferably from 3.0 V to 3.8 V.

The lithium-ion battery of the present invention has a positive electrode that contains the electrode-active material of the present invention.

A method for manufacturing an electrode-active material of the present invention includes a step of forming a mixture by mixing particles composed of Li_{w}AₓDO₄ (here, A represents 1 or 2 kinds selected from the group consisting of Mn and Co, D represents 1, 2, or more kinds selected from the group consisting of P, Si, and S, 0<w≦4, and 0<x≦1.5) with an Li source, and E source (here, E represents either Fe or Fe and Ni), a G source (here, G represents 1, 2, or more kinds selected from the group consisting of P, Si, and S), and an organic compound, a step of then forming a dried material by drying the mixture, and a step of then generating a carbonaceous electron-conducting material by carbonizing the organic compound by performing thermal treatment on the dried material in a non-oxidative atmosphere, such that a coating layer composed of a complex consisting of Li_{y}E_{z}GO₄ (here, represents either Fe or Fe and Ni, G represents 1, 2, or more kinds selected from the group consisting of F, Si, and S, 0<y≦2, and 0<z≦1.5) and the carbonaceous electron-conducting material is generated on the surface of the particle composed of Li_{w}AₓDO₄.

It is preferable to mix the Li source, the E source, the G source, and the organic compound together such that these become a uniform liquid phase.

### Advantageous Effects of Invention

According to the electrode-active material of the present invention, in a discharge curve of the electrode-active material obtained by coating the surface of a particle composed of Li_{w}AₓDO₄ (here, A represents 1 or 2 kinds selected from the group consisting of Mn and Co, D represents 1, 2, or more kinds selected from the group consisting of P, Si, and S, 0<w≦4, and 0<x≦1.5) with a coating layer containing Li_{y}E_{z}GO₄ (here, E represents either Fe or Fe and Ni, G represents 1, 2, or more kinds selected from the group consisting of P, Si, and S, 0<y≦2, and 0<z≦1.5), a second region which follows a first region showing a substantially constant discharge potential and shows a drop in a discharge potential includes a third region in which a rate of change in a discharge potential is lower than an average rate of change in a discharge potential of the second region. Accordingly, the third region shows a shoulder-like or step-like reaction curve formed when the electrode-active material reacts at a potential lower than a reaction potential of an active material composed of the Li_{w}AₓDO₄. Consequentially, by detecting the third region, the state of a late stage of discharge can be easily detected, and as a result, the endpoint of a discharge capacity of the electrode-active material can be easily estimated.

The lithium-ion battery of the present invention has a positive electrode that contains the electrode-active material of the present invention. Accordingly, the state of a late siege of discharge can be easily detected, and the endpoint of a discharge capacity can be easily estimated. Consequentially, if the lithium-ion battery is applied to a power supply of a device, it is possible to prevent voltage from rapidly dropping at the late stage of discharge and ceasing the device to malfunction.

As described above, the present invention can provide a lithium-ion battery which has high voltage, high energy density, and high load characteristics and is excellent in long-term cycle stability and safety.

According to the method for detecting a discharge state of an electrode-active material of the present invention, in a discharge curve of an electrode-active material obtained by coating the surface of a particle composed of Li_{w}AₓDO₄ (here, A represents 1 or 2 binds selected from the group consisting of Mn and Co, D represents 1, 2, or more kinds selected from the group consisting of P, Si, and S, 0<w≦4, and 0<x≦1.5) with a coating layer containing Li_{y}E_{z}GO₄ (here, E represents either Fe or Fe and Ni, G represents 1, 2, or more kinds selected from, the group consisting of P, Si, and S, 0<y≦2, and 0<z≦1.5), within a second region which follows a first region showing a substantially constant discharge potential and shows a drop in a discharge potential, a third region in which a rate or change in a discharge potential is lower than an average rate of change in a discharge potential of the second region is detected. Accordingly, the state of a late stage of discharge can be easily detected, and as a result, the endpoint of a discharge capacity of the electrode-active material can be easily estimated.

According to the electrode-active material of the present invention, in a discharge curve of the electrode-active material obtained by coating the surface of a particle composed of Li_{w}AₓDO₄ (here, A represents 1 or 2 kinds selected from the group consisting of Mn and Co, D represents 1, 2, or more kinds selected from the group consisting of P, Si, and S, 0<w≦4, and 0<x≦1.5) with a coating layer composed of a complex consisting of Li_{y}E_{z}GO₄ (here, E represents either Fe or Fe and Ni, G represents 1, 2, or more kinds selected from the group consisting of P, Si, and S, 0<y≦2, and 021 z≦1.5) and a carbonaceous electron-conducting material, a second region which follows a first region showing a substantially constant discharge potential and shows a drop in a discharge potential includes a third region in which a rate of change in a discharge potential is lower than an average rate of change in a discharge potential of the second region. Accordingly, the third region shows a shoulder-like or step-like reaction curve formed when the electrode-active material reacts at a potential lower than a reaction potential of an active material composed of the Li_{w}AₓDO₄. Therefore, by detecting the third region, the state of a late stage of discharge can be easily detected, and as a result, the endpoint of a discharge capacity of the electrode-active material can be easily estimated.

The lithium-ion battery of the present invention has a positive electrode that contains the electrode-active material of the present invention. Accordingly, the state of a late stage of discharge can be easily detected, and the endpoint of a discharge capacity can be easily estimated. Consequentially, if the lithium-ion battery is applied to a power supply of a device, it is possible to prevent voltage from rapidly dropping at the late stage of discharge and causing the device to malfunction.

As described above, the present invention can provide a lithium-ion battery which has high voltage, high energy density, and high load characteristics and is excellent in long-term cycle stability and safety.

The method for manufacturing an electrode-active material of the present invention includes a step of forming a mixture by mixing particles composed of Li_{w}AₓDO₄ (here, A represents 1 or 2 kinds selected from the group consisting of Mn and Co, D represents 1, 2, or more kinds selected from the group consisting of P, Si, and S, 0<w≦4, and 0<x≦1.5) with an Li source, and E source (here, E represents either Fe or Fe and Ni), a G source (here, G represents 1, 2, or more kinds selected from the group consisting of P, Si, and S), and an organic compound, a step of then forming a dried material by drying the mixture, and a step of then generating a carbonaceous electron-conducting material by carbonizing the organic compound by performing thermal treatment on the dried material in a non-oxidative atmosphere, such that a coating layer composed of a complex consisting of Li_{y}E_{z}GO₄ (here, E represents either Fe or Fe and Ni, G represents 1, 2, or more kinds selected from the group consisting of P, Si, and S, 0<y≦2, and 0<z≦1.5) and the carbonaceous electron-conducting material is generated on the surface of the particle composed of Li_{w}AₓDO₄. Accordingly, an electrode-active material which makes it possible to easily detect the state of a late stage of discharge and to easily estimate the endpoint of a discharge capacity can be easily prepared.

### BRIEF DESCRIPTION OF DRAWINGS

FIG. 1 is a cross-sectional view showing an electrode-active material of an embodiment of the present invention.

FIG. 2 is a scanning electron microscope (SEM) image showing an electrode-active material of Example 4 of the present invention.

FIG. 3 is a view showing a charge-discharge curve of a lithium-ion battery of Example 1 of the present invention.

FIG. 4 is a view showing a charge-discharge curve of a lithium-ion battery of Example 3 of the present invention.

FIG. 5 is a view showing a charge-discharge curve of a lithium-ion battery of Example 5 of the present invention.

FIG. 6 is a view showing a charge-discharge curve of a lithium-ion battery of a comparative example.

FIG. 7 is a view showing a differential curve of discharge of a lithium-ion battery of Example 3 of the present invention.

### DESCRIPTION OF EMBODIMENTS

Embodiments of the electrode-active material, the lithium-ion battery, the method for detecting a discharge state of an electrode-active material, and the method for manufacturing an electrode-active material of the present invention will be described.

Herein, the embodiments are specifically described to further promote understanding of the gist of the present invention, and unless otherwise specified, the embodiments do not limit the present invention.

[Electrode-Active Material]

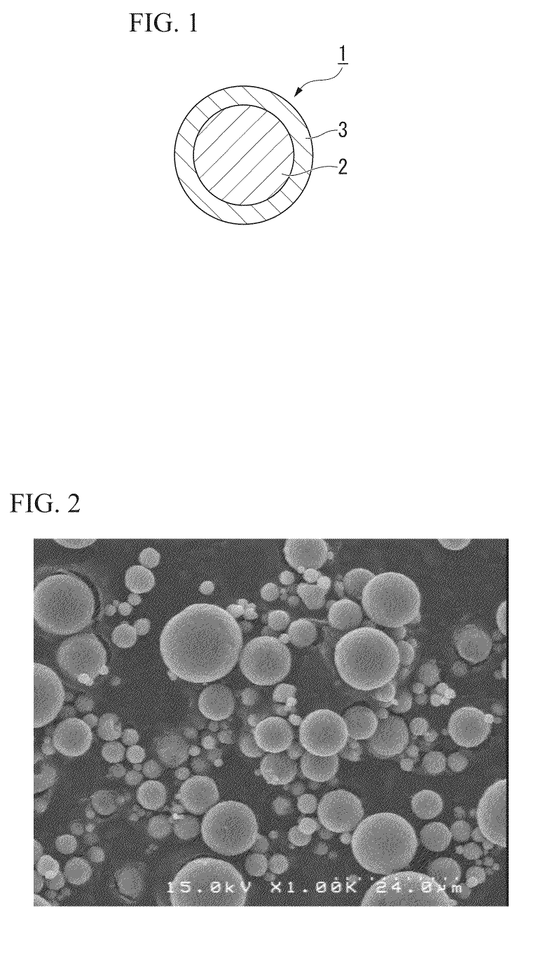

FIG. 1 is a cross-sectional view showing an electrode-active material of an embodiment of the present invention. In an electrode-active material 1, the surface of a particle 2 (hereinafter, the particle will be referred to as an Li_{w}AₓDO₄ particle 2) composed of Li_{w}AₓDO₄ (here, A represents 1 or 2 kinds selected from the group consisting of Mn and Co, D represents 1, 2, or more kinds selected from the group consisting of P, Si, and S, 0<w≦4, and 0<x≦1.5) has been coated with a coating layer 3 containing Li_{y}E_{z}GO₄ (here, E represents either Fe or Fe and Ni, G represents 1, 2, or more kinds selected from the group consisting of P, Si, and S, 0<y≦2, and 0<z≦1.5).

An average particle size of the Li_{w}AₓDO₄ particle 2 is preferably from 5 nm to 500 nm and more preferably from 20 nm to 200 nm.

If the average particle sire is smaller than 5 nm, the crystalline structure may be destroyed due to change in a volume resulting from charge and discharges and if the average particle size is greater than 500 nm, the amount of electrons supplied into the particle becomes insufficient, and the utilization efficiency decreases. For this reason, it is preferable to set the average particle site within the above range.

The coating layer 3 may be a coating layer containing the Li_{y}E_{z}GO₄, and more specifically, it is one of the following coating layers (1) and (2).

(1) A coating layer composed of Li_{y}E_{z}GO₄ that is generated by mixing the Li_{w}AₓDO₄ particle 2 with an Li source, an E source (here, E represents either Fe or Fe and Ni), and a G source (here, G represents 1, 2, or more kinds selected from the group consisting of P, Si, and S) and then performing thermal treatment on the mixture in a non-oxidative atmosphere.

(2) A coating layer composed of a complex, consisting of Li_{y}E_{z}GO₄ and a carbonaceous electron-conducting material that is generated by mixing the Li_{w}AₓDO₄ particle 2 with an Li source, an E source (here, E represents either Fe or Fe and Ni), a G source (here, G represents 1, 2, or more kinds selected from the group consisting of P, Si, and S), and an organic compound and then performing thermal treatment on the mixture in a non-oxidative atmosphere.

When the amount of the carbonaceous electron-conducting material is converted into a carbon amount, the content of the carbonaceous electron-conducting material in the coating layer (2) is preferably from 30% by mass to 99% by mass, and more preferably from 50% by mass to 95% by mass expressed in terms of carbon.

If the carbonaceous electron-conducting material contains a carbonaceous material in an amount of 30% by mass to 99% by mass expressed in terms of carbon, an intended electron conductivity can be provided to the electrode-active material 1.

Moreover, if the compositional ratio among the Li_{w}AₓDO₄ particle 2, the Li source, the E source, and the G source and the content of each of these components are appropriately changed, an intended residual capacity-detecting function can be easily provided.

The thickness of the coating layer 3 is preferably from 0.1 nm to 25 nm, and more preferably from 2 nm to 10 nm.

If the thickness is smaller than 0.1 nm, the electron conductivity of the coating layer 3 becomes insufficient, and hence the electron conductivity of the electrode-active material 1 greatly deteriorates. If the thickness is greater than 25 nm, the proportion of the high-voltage active material in the electrode-active material 1 is reduced, and this makes it difficult to effectively use the active material. For this reason, it is preferable to set the thickness within the above range.

As described above, considering the average particle rise of the Li_{w}AₓDO₄ particle 2 and the thickness of the coating layer 3, the average particle else of the electrode-active material 1 is from 5 nm to 550 nm, and preferably from 20 nm to 300 nm.

A range of the average particle size of the electrode-active material 1 is narrow, and the electrode-active material 1 is excellent in monodispersity. Accordingly, when the electrode-active material 1 is used for a positive electrode of a lithium-ion battery, electrical characteristics of the positive electrode become extremely uniform, and variation in characteristics also becomes extremely small. Consequentially, the obtained lithium-ion battery has high voltage, high energy density, and high load characteristics and is excellent in long-term cycle stability and safety.

The surface or the coating layer 3 may be further coated with a second coating layer containing a carbonaceous electron-conducting material.

When the amount of the carbonaceous electron-conducting material is converted into a carbon amount as in the coating layer 3, the content of the carbonaceous electron-conducting material in the second coating layer is preferably from 30% by mass to 99% by mass, and more preferably from 50% by mass to 95% by mass expressed in terms of carbon.

If the carbonaceous electron-conducting material contains a carbonaceous material in an amount of 30% by mass to 99% by mass expressed in terms of carbon, intended electron conductivity can be provided to the electrode-active material in which the surface of the Li_{w}AₓDO₄ particle 2 has been coated with the coating layer having a double-layer structure.

[Method for Manufacturing Electrode-Active Material (1)]

This method for manufacturing an electrode-active material is a method for manufacturing the electrode-active material in which the surface of the Li_{w}AₓDO₄ particle 2 has been coated with the coating layer 3 composed of Li_{y}E_{z}GO₄. This method includes a step of forming a mixture by mixing an Li_{w}AₓDO₄ particle with an Li source, an E source, a G source, and water, a step of then forming a dried material by drying the mixture, and a step of then performing thermal treatment on the dried material in a non-oxidative atmosphere, such that a coating layer composed of Li_{y}E_{z}GO₄ is generated on the surface of the Li_{w}AₓDO₄ particle.

Herein, the Li_{w}AₓDO₄ particle can be obtained in a manner in which an Li source, an A source, and a D source are added to a solvent containing water as a main component such that a molar ratio among the sources (Li source:A source:D source) becomes w:x:l, the resultant is stirred to form a precursor solution of Li_{w}AₓDO₄; and the precursor solution is put into a pressure-resistant container and subjected to hydrothermal treatment at a high temperature which is, for example, from 120° C. to 250° C. and at a high pressure which is, for example, 0.2 MPa or higher for 1 hour to 24 hours.

As the Li source used in the method for manufacturing an electrode-active material, for example, 1, 2, or more kinds selected from the group consisting of inorganic acid salts of lithium, such as lithium hydroxide (LiOH), lithium carbonate (Li₂CO₃), lithium chloride (LiCl), and lithium phosphate (Li₃PO₄), organic acid salts of lithium such as lithium acetate (LiCH₃COO) and lithium oxalate ((COOLi)₂), and hydrates thereof are preferably used. Particularly, raw materials such as lithium chloride and lithium acetate that form a uniform solution phase together with the E source, the G source, and the organic compound are preferable.

As the E source, compounds containing either Fe or Fe and Ni, for example, iron compounds such as iron (II) chloride (FeCl₂), iron (II) sulfate (FeSO₄), and iron (II) acetate (Fe(CH₃COO)₂) or hydrates thereof, and mixtures consisting of these iron compounds or hydrates thereof and nickel compounds such, as nickel (II) chloride (NiCl₂), nickel (II) sulfate (NiSO₄), and nickel (II) acetate (Ni(CH₃COO)₂) or hydrates thereof, are preferably used.

As the G source, 1, 2, or more kinds selected from the group consisting of phosphoric acid sources such as phosphoric acids such as orthophosphoric acid (H₃PO₄) and metaphosphoric acid (HPO₃), ammonium dihydrogen phosphate (NH₄H₂PO₄), diammonium hydrogen phosphate ((NH₄)₂HPO₄), ammonium phosphate ((NH₄)₃PO₄), and hydrates thereof, Si sources such as silicon oxide (SiO₂) and a silicon alkoxide like silicon tetramethoxide (Si(OCH₃)₄), and S sources such as diammonium sulfate ((NH₄)₂SO₄) and sulfuric acid (H₂SO₄) are preferably used.

Particularly, orthophosphoric acid, sulfuric acid, and the like are preferable since these form a uniform solution phase together with the Li source, the E source, and the organic compound.

The Li source, the E source, the G source, and the solvent such as water may be used in combination forming a uniform solution phase, and there is no particular limitation on the material of each of them.

Furthermore, in order to form a uniform solution phase, a pH regulator such as an acid or an alkali may be added thereto. group consisting of inorganic acids such as hydrochloric acid, sulfuric acid, and nitric acid and organic acids such as formic, acid, acetic acid, citric acid, lactic acid, and ascorbic acid are preferably used.

In this manufacturing method, a mixture obtained by mixing the Li_{w}AₓDO₄ particle with the Li source, the E source, the G source, and a solvent such as water is formed into a dried material by being dried for 1 to 48 hours at a temperature of 50° C. to 200° C. in a dryer; and then thermal treatment is performed on the dried material in a non-oxidative atmosphere, for example, in an inert atmosphere such as nitrogen (N₂) gas or in a reducing atmosphere such as nitrogen (N₂) gas containing hydrogen (H₂) gas in an amount of 2% by volume to 5% by volume, whereby a coating layer composed of Li_{y}E_{z}GO₄ is generated on the surface of the Li_{w}AₓDO₄ particle.

For drying the mixture obtained by mixing the Li_{w}AₓDO₄ particle with the Li source, the E source, the G source, and a solvent such as water, a spray dryer can also be used. If the spray dried is used for drying, an electrode-active material having a spherical shape is obtained, and as a result, the improvement of repletion of the positive electrode and the improvement of productivity can be expected.

The thermal treatment conditions may be set within a range of temperature and time in which the coating layer composed of Li_{y}E_{z}GO₄ which undergoes an electrochemical reaction at a lower potential compared to the active material of the core, such as lithium manganese phosphate (LiMnPO₄) or lithium cobalt phosphate (LiCoPO₄), is generated on the surface or the Li_{w}A_{z}DO₄ particle. For example, the temperature of the thermal treatment is preferably from 500° C. to 1,000° C., and the time of thermal treatment is preferably from 1 hour to 24 hours, though the time also depends on the temperature at the time of the thermal treatment.

In the manner described above, it is possible to easily prepare the electrode-active material 1 in which the surface of the Li_{w}AₓDO₄ particle 2 has been coated with the coating layer 3 composed of Li_{y}E_{z}GO₄ and which has an average particle size of 5 nm to 550 nm and preferably from 20 nm to 300 nm.

Herein, the surface of the coating layer 3 may be further coated with a second coating layer containing a carbonaceous electron-conducting material.

[Method for Manufacturing Electrode-Active Material (2)]

This method for manufacturing an electrode-active material is a method for manufacturing the electrode-active material 1 in which the surface of the LiₓAₓDO₄ particle 2 has been coated with the coating layer 3 composed of a complex consisting of Li_{y}E_{z}GO₄ and a carbonaceous electron-conducting material. This method includes a step of forming a mixture by mixing the Li_{w}AₓDO₄ particle with an Li source, an E source, a G source, and an organic compound, a step of then forming a dried material by drying the mixture, and a step of then generating a carbonaceous electron-conducting material by carbonizing the organic compound by performing thermal treatment on the dried material in a non-oxidative atmosphere, such that a coating layer composed of a complex consisting of Li_{y}E_{z}GO₄ and the carbonaceous electron-conducting material is generated on the surface of the Li_{w}AₓDO₄ particle.

The method for manufacturing an electrode-active material (2) is erectly the same as the method for manufacturing an electrode-active material (1) in regard to the Li source, the E source, the G source, and the like, except that the method (2) includes a step of generating a carbonaceous electron-conducting material by carbonizing the added organic compound.

Herein, as the E source, since a reduction effect resulting from the organic compound can be expected, iron compounds like trivalent iron compounds such as iron (III) nitrate (Fe(NO₃)₃), iron (III) chloride (FeCl₃), and iron (III) citrate (FeC₆H₅O₇) are preferably used.

Particularly, iron (II) chloride (FeCl₂), iron (II) acetate (Fe(CH₃COO)₂), iron (II) sulfate (FeSO₄), iron (III) nitrate (Fe(NO₃)₃), iron (III) citrate (FeC₆H₅O₇), and the like are preferably since these form a uniform solution phase together with the Li source, the G source, and the organic compound.

The organic compound in not particularly limited as long as it is an organic compound generating carbon by being subjected to thermal treatment in a non-oxidative atmosphere. Examples thereof include higher monols such as hexanol and octanol, unsaturated monols such as allyl alcohol, propynol (propargyl alcohol), and terpineol, saccharides such as glucose, sucrose, and lactose, polyvinyl alcohol (PVA), and the like. Particularly, glucose, sucrose, polyvinyl alcohol (PVA), and the like are preferable, since these form a uniform solution phase together with the Li source, the E source, the G source, and the organic compound.

The Li source, the E source, the G source, and the organic compound may be used in combination forming a uniform solution phase, and there is no particular limitation of the material of each of them.

Moreover, in order to form a uniform solution phase, a pH regulator such as an acid or an alkali may be added thereto.

As the pH regulator, 1, 2, or more kinds selected from the group consisting of inorganic acids such as hydrochloric acid, sulfuric acid, and nitric acid and organic acids such as formic acid, acetic acid, citric acid, lactic acid, and ascorbic acid are preferably used. Particularly, an organic acid is preferable since it does not generate residues other than carbon after pyrolysis.

There is no particular limitation on the concentration of the organic compound in the mixture (slurry) obtained by mixing the Li source, the E source, the G source, and the organic compound together. However, in order to uniformly form a coating layer, which is composed of a complex consisting of Li_{y}E_{z}GO₄ and the carbonaceous electron-conducting material, on the surface of the Li_{w}AₓDO₄ particle, the concentration is preferably from 1% by mass to 25% by mass.

The solvent dissolving the organic compound is not particularly limited as long as it dissolves the organic compound. Examples thereof include water, alcohols such as methanol ethanol, 1-propanol, 2-propanol (isopropyl alcohol: IPA), butanol, pentanol, hexanol, octanol, and diacetone alcohol, esters such as ethyl acetate, butyl acetate, ethyl lactate, propylene glycol monomethyl ether acetate, propylene glycol monoethyl ether acetate, and γ-butyrolactone, and ethers such as diethyl ether, ethylene glycol monomethyl ether (methyl cellosolve), ethylene glycol monoethyl ether (ethyl cellosolve), ethylene glycol monobutyl ether (butyl cellosolve), diethylene glycol monomethyl ether, and diethylene glycol monoethyl ether.

Examples of the solvent also include ketones such as acetone, methyl ethyl ketone (MEK), methyl isobutyl ketone (MIEK), acetyl acetone, and cyclohexanone, amides such as dimethylformamide, N,N-dimethylacetoacetamide, and N-methylpyrrolidone, and glycols such as ethylene glycol, diethylene glycol, and propylene glycol. One kind of these may be used singly, or two or more kinds thereof may be used by being mixed with each other. In view of safety, cost, and the property of easily dissolving the Li source, the E source, the G source, and the organic compound, water is preferable.

In this manufacturing method, a mixture obtained by mixing the Li_{w}AₓDO₄ particle with the Li source, the E source, the G source, the organic compound, and a solvent which is used as necessary is dried for 1 hour to 48 hours at a temperature of 50° C. to 200° C. in a dryer so as to form a dried material; and a carbonaceous electron-conducting material is generated by carbonizing the organic compound by means of performing thermal treatment on the dried material in a non-oxidative atmosphere, for example, in an inert atmosphere such as nitrogen (N₂) gas or in a reducing atmosphere such as nitrogen (N₂) gas containing hydrogen (H₂) gas in an amount of 2% by volume to 5% by volume, such that a coating layer composed of a complex consisting of Li_{y}E_{z}GO₄ and the carbonaceous electron-conducting material is generated on the surface of the Li_{w}AₓDO₃.

For drying the mixture obtained by mixing the Li_{w}AₓDO₄ particle with the Li source, the E source, the G source, the organic compound, and a solvent which is used as necessary, a spray dryer can also be used. If the spray dryer is used for drying, an electrode-active material having a spherical shape is obtained, and as a result, the improvement of repletion of the positive electrode and the improvement of productivity can be expected.

The thermal treatment conditions may be set within a range of temperature and time in which a carbonaceous electron-conducting material is generated by carbonizing an organic compound, and thus the coating layer composed of a complex consisting of Li_{y}E_{z}GO₄ which undergoes an electrochemical reaction at a lower potential compared to the active material of the core, such as lithium manganese phosphate (LiMnPO₄) or lithium cobalt phosphate (LiCoPO₄), and a carbonaceous electron-conducting material is generated on the surface of the Li_{w}AₓDO₄ particle. For example, the temperature of the thermal treatment is preferably from 500° C. to 1,000° C., and the time of thermal treatment is preferably from 1 hour to 24 hours, though the time also depends on the temperature at the time of the thermal treatment.

In the manner described above, it is possible to easily prepare the electrode-active material 1 in which the surface of the Li_{w}AₓDO₄ particle 2 has been coated with the coating layer 3 composed a complex consisting of Li_{y}E_{z}GO₄ and a carbonaceous electron-conducting material and which has an average particle size of 5 nm to 550 nm and preferably about 20 nm to 300 nm.

[Method for Detecting Discharge State of Electrode-Active Material]

A method for detecting a discharge state of an electrode-active material of the present embodiment is a method in which in a discharge curve of an electrode-active material obtained by coating the surface of Li_{w}AₓDO₄ particle with a coating layer containing Li_{y}E_{z}GO₄, within a second region which follows a first region showing a substantially constant discharge potential and shows a drop in a discharge potential, a third region in which a rate of change in a discharge potential is lower than an average rate of change in a discharge potential of a second region is detected.

For example, the aforementioned electrode-active material is made into a thin plate-like or thin film-like electrode-active material by means of pressing, a doctor blade, and the like, and a discharge curve of the thin plate-like or thin film-like electrode-active material is obtained. In this way, within the second region in the discharge curve of the electrode-active material, the third region in which a rate of change in a discharge potential is lower than an average rate of change in a discharge potential of the second region can be detected.

Accordingly, when such an electrode-active material is applied to a positive electrode of a lithium-ion battery, the state of a late stage of discharge can be easily detected, and consequentially, the endpoint of a discharge capacity or the electrode-active material can be easily estimated.

If a positive electrode using such an electrode-active material is used as a positive electrode of a lithium-ion battery, and a discharge curve of the lithium-ion battery is obtained, it is preferable since the state of a late stage of discharge of the electrode-active material which has been actually mounted on the lithium-ion battery can be detected.

As described above, by detecting the third region, in which a rate of change in a discharge potential is lower than an average rate of change in a discharge potential of the second region, within the second region of the discharge curve of the electrodes-active material, the state of a late stage of discharge can be easily detected. As a result, the endpoint of a discharge capacity or the electrode-active material can be easily estimated.

[Lithium-Ion Battery]

A lithium-ion battery of the present embodiment has a positive electrode that contains the electrode-active material or the present embodiment.

In order to prepare the positive electrode of the present embodiment, the aforementioned electrode-active material is mixed with a binder composed of binder resin and a solvent, thereby preparing a coating material for forming an electrode or a paste for forming an electrode. At this time, a conductive and such as carbon black may be added thereto as necessary.

As the binder, that is, the binder resin, for example, a polytetrafluoroethylene (PTFE) resin, a polyvinylidene fluoride (PVdF) resin, fluororubber, and the like are preferably used.

A mixing ratio between the electrode-active material and the binder resin is not particularly limited, and for example, the ratio of the binder resin to 100 parts by mass of the electrode-active material is from 1 part by mass to 30 parts by mass, and preferably from 3 parts by mass to 20 parts by mass.

As a solvent used for either the coating material for forming an electrode or the paste for forming an electrode, the same solvent as the aforementioned solvent dissolving an organic compound is preferable, hence the description thereof will not be repeated.

Next, one surface of a metal foil is coated with the coating material for forming an electrode or with the paste for forming an electrode. Thereafter, the resultant is dried, thereby obtaining a metal foil in which a coating film composed of a mixture consisting of the electrode material and the binder resin has been formed on one surface.

Subsequently, the coating film is pressurized and compressed, followed by drying, thereby preparing a current collector (electrode) having a positive electrode layer on one surface of the metal foil.

By using the current collector (electrode) as a positive electrode, a lithium-ion battery can be obtained.

In a discharge curve of such a lithium-ion battery, a second region, which follows a first region showing a substantially constant discharge potential and shows a drop in a discharge potential, includes a third region (hereinafter, referred to as a “shoulder portion”) in which a rate of change in a discharge potential is lower than an average rate of change in a discharge potential of the second region.

Herein, a capacity at 60° C. of the shoulder portion is preferably from 1/20 to ⅓ of the maximum value of a discharge capacity.

The capacity at 60° C. of the shoulder portion is limited to the above range for the following reason. If the capacity at 60° C. is set within the above range, a shoulder-like or step-like reaction curve formed when the electrode-active material reacts at a potential loner than a reaction potential of an active material composed of the Li_{w}AₓDO₄ can be sufficiently detected, and a residual capacity remaining after the detection can be sufficiently secured. As a result, it is possible to avoid a serious problem in which a device malfunctions due to a rapid drop in voltage at the late stage of discharge, and additionally, the capacity of a high-potential portion may not be greatly impaired.

In the lithium-ion battery, a discharge potential at 60° C. of the shoulder portion is detected so as to confirm the fact that the detected value is within the above range. In this way, the state of a late stage of discharge can be easily detected, and consequentially, the endpoint of a discharge capacity of the electrode-active material can be easily estimated.

In the lithium-ion battery, a reaction potential at 60° C. of the shoulder portion is preferably from 3.0 V to 3.3 V.

The reaction potential at 60° C. of the shoulder portion is limited to the above range for the following reason. If the reaction potential at 60° C. is set within the above range, the shoulder portion has a potential clearly different from that of the high-potential portion. Accordingly, the detection can be easily performed, and energy of the portion having the residual capacity can be sufficiently secured to a high extent.

As described so far, according to the electrode-active material 1 of the present embodiment, the surface of the Li_{w}AₓDO₄ particle 2 is coated with the coating layer 3 composed of either Li_{y}E_{z}GO₄ or the complex consisting of Li_{y}E_{z}GO₄ and a carbonaceous electron-conducting material, and in the discharge curve of the electrode-active material 1, the second region which follows the first region showing a substantially constant discharge potential and shows a drop in a discharge potential includes the third region in which a rate of change in a discharge potential is lower than an average rate of change in a discharge potential of the second region. Accordingly, the third region shows a shoulder-like or step-like reaction curve formed when the electrode-active material reacts at a potential lower than the reaction potential of the Li_{w}AₓDO₄ particle 2. Consequentially, by detecting the shoulder portion, the state of a late stage of discharge can be easily detected, and as a result, the endpoint of a discharge capacity of the electrode-active material 1 can be easily estimated.

According to the method for detecting a discharge state of the electrode-active material 1 of the present embodiment, in a discharge curve of the electrode-active material 1, which is obtained by coating the surface of the Li_{w}AₓDO₄ particle 2 with the coating layer 3 containing Li_{y}E_{z}GO₄, within the second region which follows the first region showing a substantially constant discharge potential and shows a drop in a discharge potential, the third region in which a rate of change in a discharge potential is lower than an average rate of change in a discharge potential of the second region is detected. Consequentially, the state of a late stage of discharge can be easily detected, and as a result, the endpoint of a discharge capacity of the electrode-active material can be easily estimated.

The lithium-ion battery of the present embodiment has a positive electrode that contains the electrode-active material of the present embodiment. Accordingly, the state of a late stage of discharge can be easily detected, and the endpoint of a discharge capacity can be easily estimated. Consequentially, if such a lithium-ion battery is applied to a power supply of a device, it is possible to prevent the voltage from rapidly dropping at the late stage of discharge and causing the device to malfunction.

As described so far, the present invention can provide a lithium-ion battery which has high voltage, high energy density, and high load characteristics and is excellent in long-term cycle stability and safety.

According to the method for manufacturing an electrode-active material of the present embodiment, an electrode-active material which makes it possible to easily detect the state of a late stage of discharge and to easily estimate the endpoint of a discharge capacity can be easily prepared.

Furthermore, according to the method, for manufacturing an electrode-active material of the present embodiment, a mixture is formed by mixing the Li_{w}AₓDO₄ particle with the Li source, the E source, the G source, and the organic compound; a dried material is then formed by drying the mixture; and then a carbonaceous electron-conducting material is generated by carbonizing the organic compound by means of performing thermal treatment on the dried material in a non-oxidative atmosphere, such that a coating layer composed of a complex consisting of Li_{y}E_{z}GO₄ and a carbonaceous electron-conducting material is generated on the surface of the particle composed of Li_{w}AₓDO₄. Accordingly, an electrode-active material which makes it possible to easily detect the state of a late stage of discharge and to easily estimate the endpoint of a discharge capacity can be easily prepared.

### EXAMPLES

Hereinafter, the present invention will be specifically described by Examples 1 to 5 and a comparative example, but the present invention is not limited to these examples.

(Synthesis of LiMnPO₄ Particle)

LiMnPO₄ common to Examples 1 to 4 and a comparative example was prepared in the following manner.

Li₃PO₄ as an Li source and a P source and MnSO₄.5H₂O as an Mn source were used, and these were dissolved in pure water such that a molar ratio among them became Li:Mn:P=3:1:1, thereby preparing 200 mL of a precursor solution.

Next, the precursor solution was put into a pressure-resistant container and subjected to hydrothermal synthesis for 24 hours at 170° C. After the reaction, the resultant was cooled to room temperature, thereby obtaining a precipitated cake-like reaction product.

Subsequently, the precipitate was washed 5 times with distilled water so as to wash off impurities, and then the moisture content thereof was kept at 30% to prevent the precipitate from being dried, thereby obtaining cake-like LiMnPO₄.

From the cake-like LiMnPO₄, a small amount of sample was collected and dried in a vacuum for 2 hours at 70° C. As a result of identifying the thus obtained powder by X-ray diffractometry, it was confirmed that single-phase LiMnPO₄ had been generated.

(Synthesis of LiCoPO₄ Particle)

LiCoPO₄ of Example 5 was prepared in the following manner.

Li₃PO₄ as an Li source and a P source and CoSO₄.7H₂O as a Co source were used, and those were dissolved in pure water such that a molar ratio among them became Li:Co:P=3:1:1, thereby preparing 200 mL of a precursor solution.

Next, the precursor solution was put into a pressure-resistant container and subjected to hydrothermal synthesis for 24 hours at 170° C. After the reaction, the resultant was cooled to room temperature, thereby obtaining a precipitated cake-like reaction product.

Subsequently, the precipitate was washed 5 times with distilled water so as to wash off impurities, and then a moisture content thereof was kept at 30% so as to prevent the precipitate from being dried, thereby obtaining cake-like LiCoPO₄.

From the cake-like LiCoPO₄, a small amount of sample was collected and dried in a vacuum for 2 hours at 70° C. As a result of identifying the thus obtained powder by X-ray diffractometry, it was confirmed that single-phase LiCoPO₄ had been generated.

### Example 1

A 10% aqueous solution of polyvinyl alcohol as an organic compound regulated to be in an amount of 5 parts by mass expressed in terms of a solid content, and LiCH₃COO as an Li source Fe(CH₃COO)₂ as a Fe source, and H₂PO₄ as a phosphoric acid source, each of which was regulated to yield 5 parts by mass expressed in terms of LiFePO₄, were put into pure water and dissolved by stirring, thereby obtaining a transparent uniform solution. 95 parts by mass of LiMnPO₄ was put into the solution and suspended by stirring, and the obtained slurry was dried for 10 hours at 100° C. by using a dryer. Thermal treatment was performed on the obtained dried material for 1 hour at 600° C., thereby obtaining an electrode-active material of Example 1.

### Example 2

An electrode-active material of Example 2 was obtained in the same manner as in Example 1, except that FeSO₄ was used as an Fe source instead of Fe(CH₃COO)₂).

### Example 3

A 10% aqueous solution of polyvinyl alcohol as an organic compound regulated to be in an amount of 5 parts by mass expressed in terms of a solid content, and LiCH₃COO as an Li source, iron (III) citrate (FeC₆H₅O₇) as an Fe source, and H₃PO₄ as a phosphoric acid source, each of which was regulated to yield an amount of 8 parts by mass expressed in terms of LiFePO₄, were put into pure water and dissolved by stirring, thereby obtaining a transparent uniform solution. 92 parts by mass of LiMnPO₄ was put into the solution and suspended by stirring, and the obtained slurry was dried for 10 hours at 100° C. by using a dryer. Thermal treatment was performed on the obtained dried material for 1 hour at 600° C., thereby obtaining an electrode-active material of Example 3.

### Example 4

An electrode-active material of Example 4 was obtained in the same manner as in Example 3, except that the slurry was dried at 120° C. by using a spray dryer, instead of being dried for 10 hours at 100° C. by using a dryer. FIG. 2 shows a scanning electron microscope (SEM) image of the electrode-active material of Example 4.

### Example 5

An electrode-active material of Example 5 was obtained in the same manner as in Example 3, except that LiCoPO₄ was used instead of LiMnPO₄.

### Comparative Example

A solution containing an organic compound, an Li source, an Fe source, and a phosphoric acid source was obtained in the same manner as in Example 1, except that LiOH and (NH₄)H₂PO₄ were used as the Li source and the phosphoric acid source respectively.

In this solution, a precipitate was formed.

Moreover, 95 parts by mass of LiMnPO₄ was put into the solution, and the resultant was subjected to stirring, drying, and thermal treatment in the same manner as in Example 1, thereby obtaining an electrode-active material of a comparative example.

(Preparation of Lithium-Ion Battery)

A positive electrode mass prepared for each of Examples 1 to 5 and the comparative example.

Herein, each of the electrode-active materials obtained in each of Examples 1 to 5 and the comparative example, acetylene black (AB) as a conductive aid, polyvinylidene fluoride (PVdF) as a binder, and N-methyl-2-pyrrolidinone (NMP) as a solvent were used, and these were mixed together, thereby preparing a paste of each of Examples 1 to 3 and the comparative example. A mass ratio of LiMnPO₄ or LiCoPO₄:AB:PVdF PVdF contained in the paste was 85:10:5.

Next, the paste was applied onto an aluminum (Al) foil having a thickness of 30 μm. The resultant was dried and then compressed under a pressure of 40 MPa, thereby preparing a positive electrode.

Subsequently, the positive electrode was punched into the shape of a disc having an area of 2 cm² by using a molding machine and then dried in a vacuum. Thereafter, by using a 2032 coin cell trade of stainless steel (SUS), a lithium-ion battery for each of Examples 1 to 5 and the comparative example was prepared in a dry Ar atmosphere. At this time, metal Li was used as a negative electrode, a porous polypropylene film was used as a separator, and 1M solution of LiPF₆ was used as an electrolytic solution. As a solvent of the LiPF₆ solution, a solvent in which a ratio between ethylene carbonate and diethyl carbonate was 1:1 was used.

[Battery Characteristics Test]

A battery characteristics test for the lithium-ion battery of each of Examples 1 to 5 and the comparative example was conducted in a manner in which the battery was charged at an environmental temperature of 60° C. and a charging current of 0.1 CA until the potential of a test electrode became a prescribed charging voltage relative to the equilibrium potential of Li; charging was halted for 1 minute; and then the battery was discharged at a discharging current of 0.1 CA until the voltage thereof became 2.0 V.

For the Mn-based lithium-ion battery of Examples 1 to 4 and the comparative example, a charging voltage was set to 4.5 V, and for the Co-based lithium-ion battery of Example 5, a charging voltage was set to 4.9 V.

In Example 2, FeSO₄ was used instead of Fe(CH₃COO)₂ as an Fe source, but a discharge curve of the example was practically the same as that of the lithium-ion battery of Example 1.

Moreover, in Example 4, drying was performed using a spray dryer instead of the dryer, but a discharge curve of the example was practically the same as that of the lithium-ion battery of Example 3. In Example 4, due to the use of the spray dryer, an electrode-active material having a spherical shape was obtained. Therefore, both the repletion of the positive electrode and the productivity were improved.

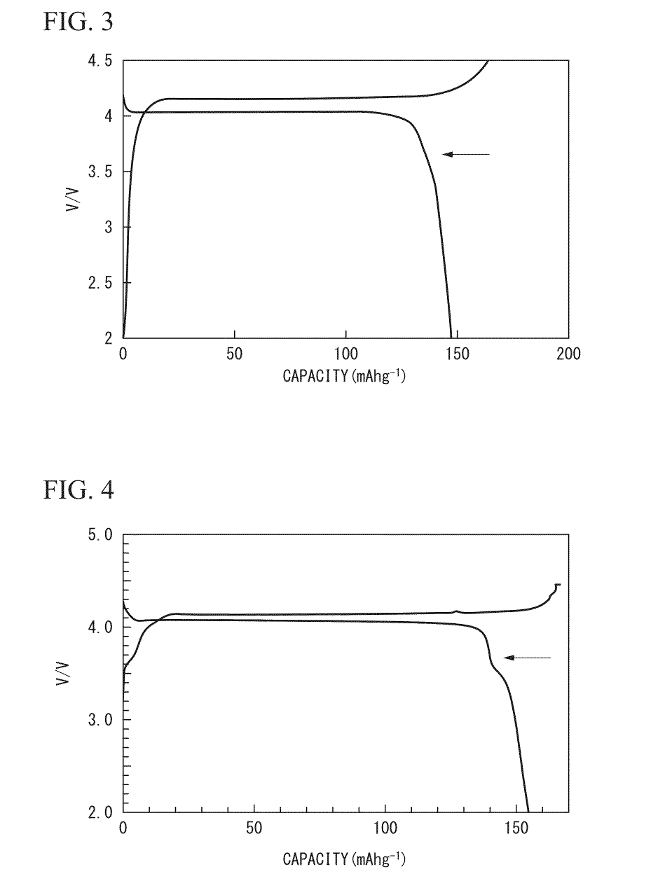

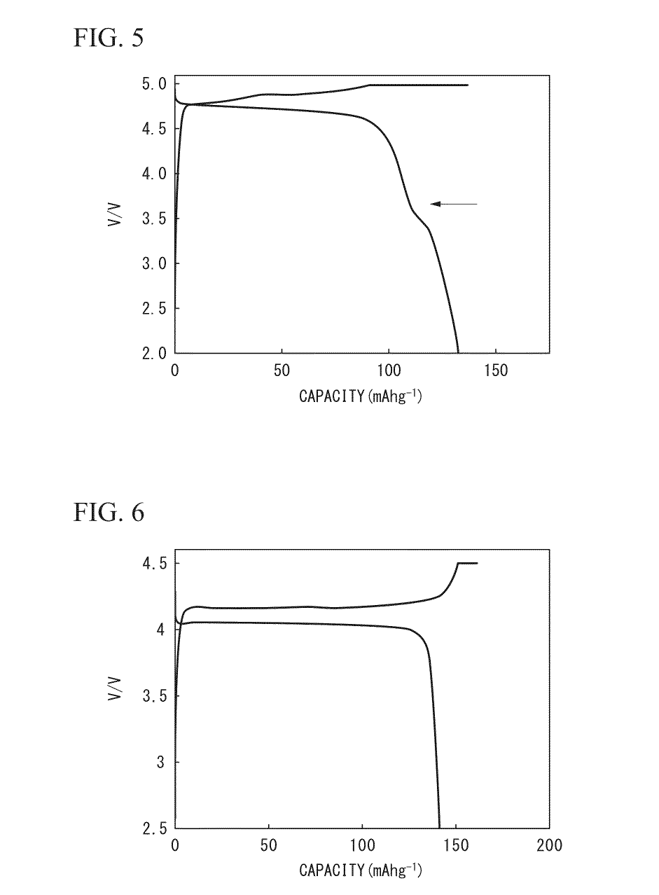

FIG. 3 shows a discharge curve at an environmental temperature of 60° C. of the lithium-ion battery of Example 1; FIG. 4 shows a discharge curve at the same temperature of the lithium-ion battery of Example 3; FIG. 5 shows a discharge curve at the same temperature of the lithium-ion battery of Example 5; and FIG. 6 shows a discharge curve at the same temperature of the lithium-ion battery of the comparative example. In FIGS. 3 to 5, the arrow indicates the position of a shoulder portion.

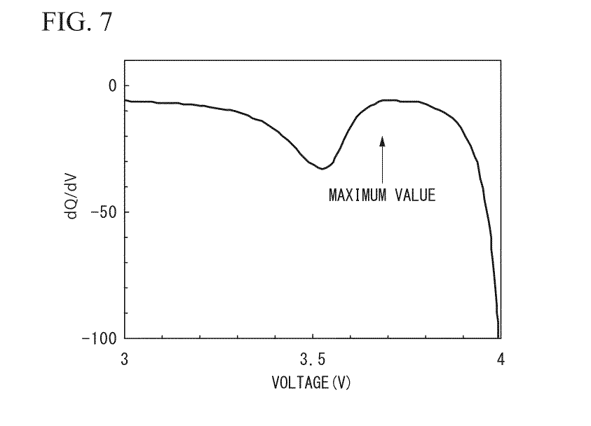

Regarding the discharge curve of the lithium-ion battery of Example 3, the capacity was differentiated by voltage, thereby obtaining a differential curve. The result is shown in FIG. 7.

An inception voltage of the shoulder portion (shoulder voltage) that was obtained from a maximum value of the differential curve was 3.70 V, and a discharge capacity (capacity before shoulder) until the starting point of the shoulder portion was 140 mAh/g. On the contrary, a discharge capacity at a point in time when the voltage became 2.00 V was 155 mAh/g, and a ratio (shoulder capacity ratio) of the capacity after the shoulder portion (capacity at 60° C. of the third region) to the total capacity (maximum value of the discharge capacity) was (155−140)/155=0.097.

The same evaluation was performed on the lithium-ion battery of each of Examples 1, 2, 4, and 5 and the comparative example. The evaluation results are shown in Table 1.

TABLE 1

| | | Capacity | | |
|---|---|---|---|---|
| | Shoulder | before | Total | Shoulder |
| | Voltage | shoulder | capacity | capacity |
| | (V) | (mAh/g) | (mAh/g) | ratio |
| Example 1 | 3.67 | 138 | 146 | 0.055 |
| Example 2 | 3.67 | 136 | 144 | 0.056 |
| Example 3 | 3.70 | 140 | 155 | 0.097 |
| Example 4 | 3.70 | 142 | 156 | 0.090 |
| Example 5 | 3.55 | 114 | 132 | 0.090 |
| Comparative | 3.49 | 140 | 142 | 0.014 |
| example | | | | |

As shown in Table 1, in Examples 1 to 5, a shoulder voltage of 3.5 V to 3.7 V resulting from LiFePO₄, which was contained in the coating layer 3 composed of a complex consisting of LiFePO₄ and a carbonaceous electron-conducting material, was confirmed, and the shoulder capacity ratio was confirmed to be 5% or higher. Consequentially, it was understood that if capacitive detection is performed using the shoulder voltage, it is possible to urge caution at a point in time when the residual capacity is 5% or higher and to have sufficient time for preventing a device from malfunctioning beforehand due to a rapid voltage drop.

On the contrary, in the comparative example, the shoulder voltage was not observed in the charge-discharge curve, and the shoulder capacity ratio obtained from the differential curve was 1.4%, which is a small value. Furthermore, although the amount of LiFePO₄ contained in the carbonaceous coating layer was the same as that of Example 1, sufficient time for preventing a device from malfunctioning beforehand due to a rapid voltage drop could not be obtained, and this led to a concern that the device may malfunction due to a rapid voltage drop.

Moreover, according to the present examples, even if LiFePO₄ was added in a small amount such as an amount less than 10% by mass with respect to LiMnPO₄, a carbonaceous coating layer that can provide excellent conductivity to LiMnPO₄ could be obtained, and the capacity reacting at high voltage that is a characteristic of LiMnPO₄ could be sufficiently maintained.

In Examples 1 to 5, in order to reflect the behavior of the electrode-active material in the data, metallic lithium was used as a negative electrode. However, instead of metallic lithium, negative electrode materials such as carbon materials including natural graphite, artificial graphite, and cokes, lithium alloys, and Li₄Ti₅O₁₂ may be used.

Moreover, although acetylene black was used as a conductive aid, carbon materials such as carbon black, graphite, Ketjen black, natural graphite, and artificial graphite may also be used.

In addition, although a solution of LiPF₆ used as an electrolytic solution, and a solvent in which a ratio between ethylene carbonate and diethyl carbonate is 1:1 was used as a solvent of the LiPF₆ solution, a solution of LiBF₄ or LiClO₄ may be used instead of LiPF₆, and propylene carbonate or diethyl carbonate was used instead of the ethylene carbonate.

Furthermore, a solid electrolyte may be used instead of the electrolytic solution and the separator.

### INDUSTRIAL APPLICABILITY

The present invention is applicable to an electrode-active material, a lithium-ion battery, and a method for detecting a discharge state of an electrode-active material.

### REFERENCE SIGNS LIST

1 electrode-active material
2 Li_{w}AₓDO₄ particle
3 coating layer

1. An electrode-active material comprising:
a particle composed of Li_{w}AₓDO₄ wherein A represents 1 or 2 kinds selected from the group consisting of Mn and Co, D represents 1, 2, or more kinds selected from the group consisting of P, Si, and S, 0<w≦4, and 0<x≦1.5; and
a coating layer formed on the particle, containing Li_{y}E_{z}GO₄ wherein E represents either Fe or Fe and Ni, G represents 1, 2, or more kinds selected from the group consisting of P, Si, and S, 0<y≦2, and 0<z≦1.5,
wherein in a discharge curve of the electrode-active material, a second region which follows a first region showing a substantially constant discharge potential and shows a drop in a discharge potential includes a third region in which a rate of change in a discharge potential is lower than an average rate of change in a discharge potential of the second region.

2. The electrode-active material according to claim 1,
wherein a capacity at 60° C. of the third region is from 1/20 to ⅓ of a maximum value of a discharge capacity.

3. The electrode-active material according to claim 2,
wherein a reaction potential at 60° C. of the third region is from 3.0 V to 3.8 V.

4. A lithium-ion battery having a positive electrode that contains the electrode-active material according to claim 1.

5. A method for detecting a discharge state of an electrode-active material comprising a particle composed of Li_{w}AₓDO₄ wherein A represents 1 or 2 kinds selected from the group consisting of Mn and Co, D represents 1, 2, or more kinds selected from the group consisting of P, Si, and S, 0<w≦4, and 0<x≦1.5; and a coating layer formed on the particle, containing Li_{y}E_{z}GO₄ wherein E represents either Fe or Fe and Ni, G represents 1, 2, or more kinds selected from the group consisting of P, Si, and S, 0<y≦2, and 0<z≦1.5,
wherein in a discharge curve of the electrode-active material, within a second region which follows a first region showing a substantially constant discharge potential and shows a drop in a discharge potential, a third region in which a rate of change in a discharge potential is lower than an average rate of change in a discharge potential of the second region is detected.

6. An electrode-active material comprising a particle composed of Li_{w}AₓDO₄ wherein A represents 1 or 2 kinds selected from the group consisting of Mn and Co, D represents 1, 2, or more kinds selected from the group consisting of P, Si, and S, 0<w≦4, and 021 x≦1.5; and a coating layer formed on the particle, composed of a complex consisting of Li_{y}E_{z}GO₄ wherein E represents either Fe or Fe and Ni, G represents 1, 2, or more kinds selected from the group consisting of P, Si, and S, 0<y≦2, and 0<z≦1.5, and a carbonaceous electron-conducting material,
wherein in a discharge curve of the electrode-active material, a second region which follows a first region showing a substantially constant discharge potential and shows a drop in a discharge potential includes a third region in which a rate of change in a discharge potential is lower than an average rate of change in a discharge potential of the second region.

7. The electrode-active material according to claim 6,
wherein a capacity at 60° C. of the third region is from 1/20 to ⅓ of a maximum value of a discharge capacity.

8. The electrode-active material according to claim 7,
wherein a reaction potential at 60° C. of the third region is from 3.0 V to 3.8 V.

9. A lithium-ion battery having a positive electrode that contains the electrode-active material according to claim 6.

10. A method for manufacturing an electrode-active material, comprising:
a step of forming a mixture by mixing a particle composed of Li_{w}AₓDO₄ wherein A represents 1 or 2 kinds selected from the group consisting of Mn and Co, D represents 1, 2, or more kinds selected from the group consisting of P, Si, and S, 0<w≦4, and 0<x≦1.5, with an Li source, an E source wherein E represents either Fe or Fe and Ni, a G source wherein G represents 1, 2, or more kinds selected from the group consisting of P, Si, and S, and an organic compound;
a step of then forming a dried material by drying the mixture; and
a step of then generating a carbonaceous electron-conducting material by carbonizing the organic compound by performing thermal treatment on the dried material in a non-oxidative atmosphere, such that a coating layer composed of a complex consisting of Li_{y}E_{z}GO₄ wherein E represents either Fe or Fe and Ni, G represents 1, 2, or more kinds selected from the group consisting of P, Si, and S, 0<y≦2, and 0<z≦1.5; and the carbonaceous electron-conducting material is generated on the surface of the particle composed of Li_{w}AₓDO₄.

11. The method for manufacturing an electrode-active material according to claim 10,
wherein the Li source, the E source, the G source, and the organic compound are mixed together such that these become a uniform liquid phase.
